(19) United States
(12) Patent Application Publication
(10) Pub. No.: US 2009/0122856 A1
(43) Pub. Date: May 14, 2009

(54) METHOD AND APPARATUS FOR ENCODING DATA

(76) Inventors: Robert BAXTER, Chapel Hill, NC (US); Roland BARTH, Ottobrunn (DE); Steve BOWYER, Raleigh, NC (US); Jonghee HAN, Cary, NC (US); Harald LORENZ, South Burlington, VT (US); Jason VARRICCHIONE, Williston, VT (US); Thomas VOGELSANG, Jericho, VT (US)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/936,829

(22) Filed: Nov. 8, 2007

(51) Int. Cl. H03K 7/04

(52) U.S. Cl. 375/239

(57) ABSTRACT

A method and apparatus for reducing the number of DQ pins and current used to access data in a memory system or data transfer device, wherein an additional bit is temporally encoded on a data word during a singular access cycle. During an access cycle, the pulse level or levels of encoded bits may determine one or more bits values in a data word being expressed, while the pulse/pulses position in time within a data access cycle determines the remaining bits.

### BACKGROUND OF THE INVENTION

In a typical computer memory system, the operation of passing a given amount of data to or from memory within a given period of time has normally been limited by the speed of the device's data access cycle, combined with the amount of data input/output (DQ) pins available to interface with peripheral circuitry. Moreover, as data transfer rates increase, the power used to transmit this data also increases, often to undesirable levels. This power increase is broadly a function of data toggle rate, data signal voltage swing, and capacitance of the physical circuitry across which the data signals are transmitted. This effect may become especially apparent in high speed memory devices, wherein the data toggling rates may become very high.

### SUMMARY OF THE INVENTION

Embodiments of the invention generally provide a method of encoding (and decoding) data to enable multiple bit data transfers during each data access cycle in a memory system or data transfer device. In one embodiment, the method includes encoding a two bit data word, wherein a pulse level occurring during an access cycle defines a first bit of the data word, and a temporal position of the pulse within the access cycle defines the second bit of the data word.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-B are block diagrams depicting a memory device and memory controller according to one embodiment of the invention.

FIG. 2 is a graphical representation of data encoding useful in understanding the present invention.

FIG. 3 is a flow diagram depicting the process of performing a read operation within a memory system per an embodiment of the invention.

FIG. 4 is a flow diagram depicting the process of performing a write operation within a memory system per an embodiment of the invention.

### DETAILED DESCRIPTION OF THE PREFERRED EMBODIMENT

Embodiments of the invention generally provide a method for reducing the number of DQ pins and current used to access data in a memory system or data transfer device, wherein an additional bit is temporally encoded on a stream of data being transferred from or written to a memory system or data transfer device during a singular data access cycle. Within the said method, the pulse level of an encoded bit pair determines the first bit of the accessed data, and the pulse's position in time determines the second. In this manner, two bits of information may be accessed in the amount of time previously taken to access one, and the number of DQ pins in the device can consequently be halved.

Embodiments of the invention may generally be used with any type of memory or data transfer device. In one embodiment, the memory may be a circuit included on a device with other types of circuits. For example, the memory may be integrated into a processor device, memory controller device, or other type of integrated circuit device. Devices into which the memory is integrated may include system-on-a-chip (SOC) devices. In another embodiment, the memory may be provided as a memory device which is used with a separate memory controller device or processor device.

In both situations, where the memory is integrated into a device with other circuits and where the memory is provided as a separate device, the memory may be used as part of a larger computer system. The computer system may include a motherboard, central processor, memory controller, the memory, a hard drive, graphics processor, peripherals, and any other devices which may be found in a computer system. The computer system may be part of a personal computer, a server computer, or a smaller system such as an embedded system, personal digital assistant (PDA), or mobile phone.

In some cases, a device including the memory may be packaged together with other devices. Such packages may include any other types of devices, including other devices with the same type of memory, other devices with different types of memory, and/or other devices including processors and/or memory controllers. Also, in some cases, the memory may be included in a device mounted on a memory module. The memory module may include other devices including memories, a buffer chip device, and/or a controller chip device. The memory module may also be included in a larger system such as the systems described above.

In some cases, embodiments of the invention may be used with multiple types of memory or with a memory which is included on a device with multiple other types of memory. The memory types may include volatile memory and non-volatile memory. Volatile memories may include static random access memory (SRAM), pseudo-static random access memory (PSRAM), and dynamic random access memory (DRAM). DRAM types may include single data rate (SDR) DRAM, double data rate (DDR) DRAM, low power (LP) DDR DRAM, and any other types of DRAM. Nonvolatile memory types may include magnetic RAM (MRAM), flash memory, resistive RAM (RRAM), ferroelectric RAM (FeRAM), phase-change RAM (PRAM), electrically erasable programmable read-only memory (EEPROM), laser programmable fuses, electrically programmable fuses (e-fuses), and any other types of nonvolatile memory.

In the present description, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Also, signal names used herein are exemplary names, indicative of signals used to perform various functions in a given memory device. In some cases, the relative signals may vary from device to device. Furthermore, the circuits and devices described below and depicted in the figures are merely exemplary of embodiments of the invention. As recognized by those of ordinary skill in the art, embodiments of the invention may be utilized with any memory device.

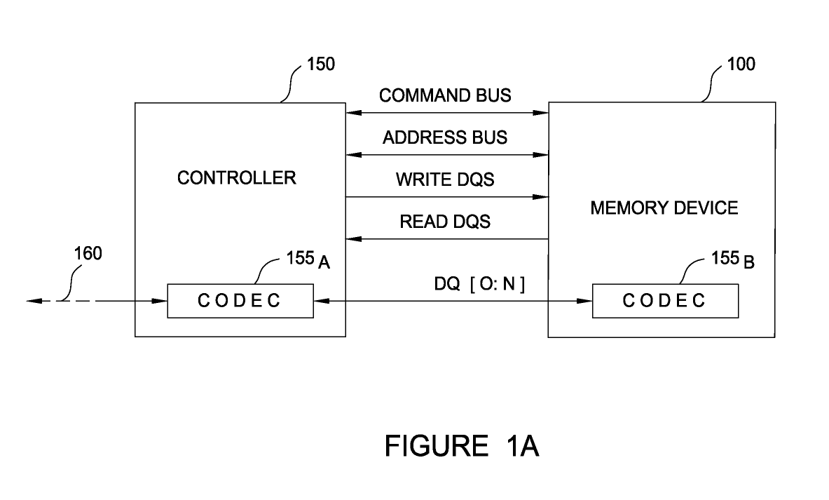

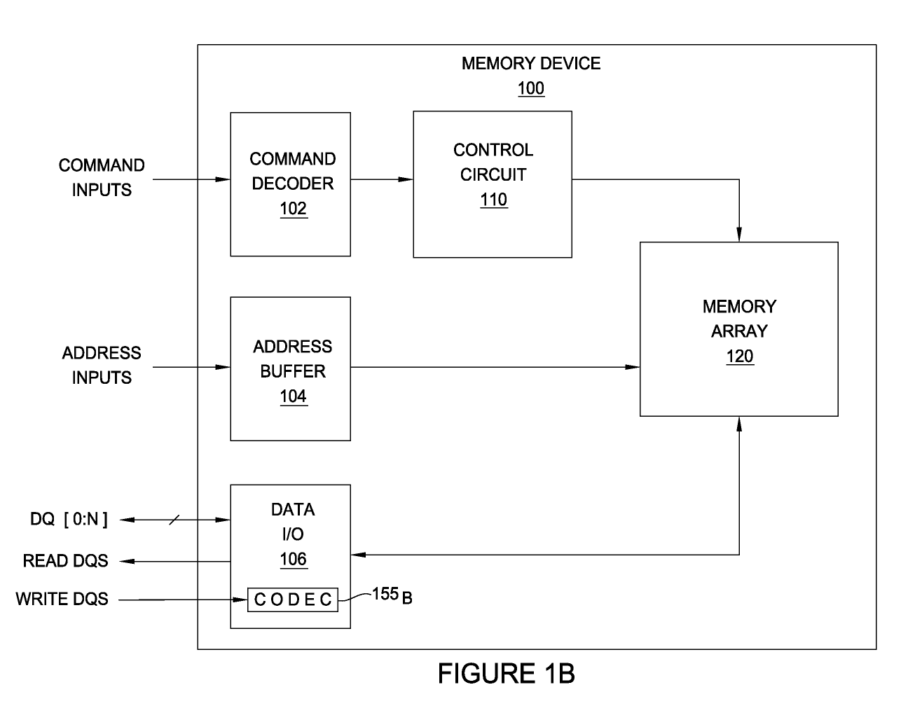

FIG. 1A is a block diagram depicting a memory device 100 and a controller 150 configured to access the memory device 100 according to one embodiment of the invention. The controller 150 may be a memory controller, processor, or any other type of controller. The controller 150 may be configured to issue commands to the memory device 100 related to memory access functions. The commands issued by the controller 150 may include mode register set commands, activate commands, commands pertinent to defining a number of bits to be transferred during a data access cycle and their temporal positions in accordance with the encoding method of this invention, and any other appropriate commands to control the memory device 100. Encoders/Decoders (CODECs) 155_{A} and 155_{B} are configured to encode and decode data according to one embodiment of the invention such that at least one additional bit is temporally encoded on a data word being transferred to/from memory system 100 during a single data access cycle. During a memory “read” operation, CODEC 155_{B} encodes the read data to be sent to controller 150, wherein it is decoded by CODEC 155_{A}. During a memory “write” operation, CODEC 155_{A} encodes the write data to be sent to memory device 100, wherein it is decoded by CODEC 155_{B.}

CODEC 155_{A} of FIG. 1A is equipped with interface 160, which includes various peripheral circuitry and/or components used to read from and/or write to memory device 100. The exact physical pin/port layout of interface 160, and signal format(s) utilized thereon, will be determined by the specific individual signal formatting protocols of the respective peripheral circuitry/components accessing memory device 100 through interface 160. Correspondingly, interface 160 may include a plurality of port configurations, and be configured to accept a plurality of different signal-types, depending upon the number of peripheral components communicating with memory device 100 by way of it, and the necessary signal format(s) of those communications.

FIG. 1A also depicts read and write data strobe (DQS) signals between controller 150 and memory device 100, which define the access cycle during which data can be outputted from or inputted to the memory device 100. In one embodiment, the memory device 100 may be an SDR DRAM and the DQS signals may provide data timing such that one word of data is transferred to or from the memory device 100 per rising edge of a DQS pulse. Optionally, in one embodiment, the memory device 100 may be a DDR DRAM and the DQS signals may provide data timing such that one word of data is transferred on both the rising and falling edge of a DQS pulse. Thus, SDR DRAM provides one active edge per DQS pulse, while DDR DRAM provides two active edges per DQS pulse. Embodiments of the invention provide a mechanism to encode multiple data bits for transfer during the time between two active edges.

FIG. 1B is a block diagram depicting the memory device 100 according to one embodiment of the invention. The memory device 100 may include address inputs and command inputs. The address inputs may be received by an address buffer 104 and the command inputs may be received by a command decoder 102. The command decoder 102 may decode commands and provide decoded command information to a control circuit 110. The control circuit 110 may use the decoded command information to send properly timed and formatted data access commands to memory array 120, which in combination with address information sent to memory array 120 by address buffer 104, may provide access to a specific location of memory array 120 in which to carry out the requested (memory read or write) operation. In some cases, the device 100 may include multiple memory arrays 120 which may be accessed in a similar fashion.

The memory device 100 may also include a data input/output (I/O) circuit 106 which may be used to input data to, and output data from, the memory array 120. One or more data lines (DQ[0:N]) may be used to input and output data to memory device 100. A write data strobe signal (write DQS) and a read DQS may be used to time the input and output of data to memory device 100, respectively.

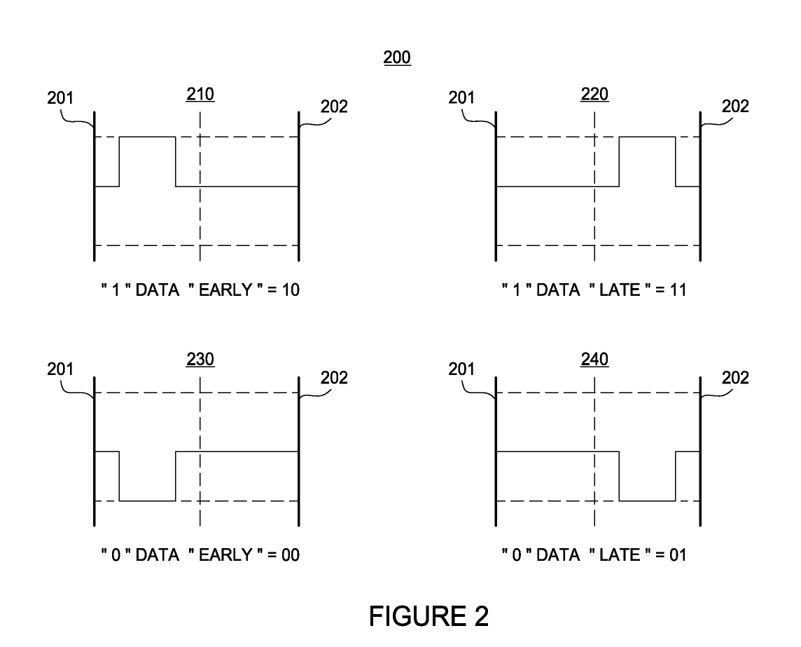

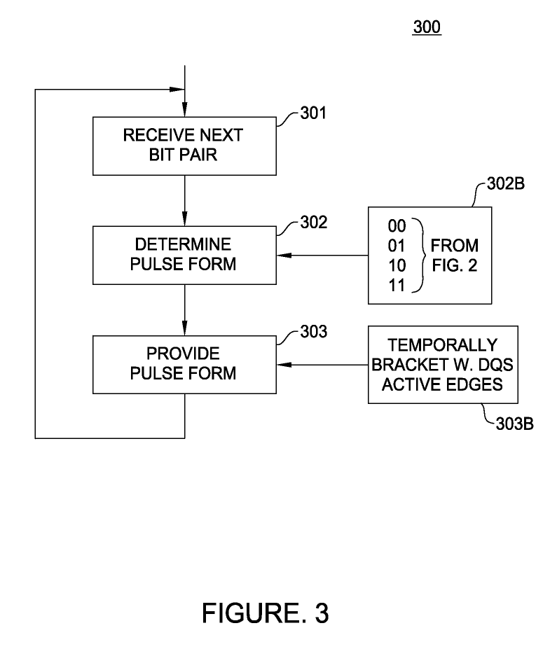

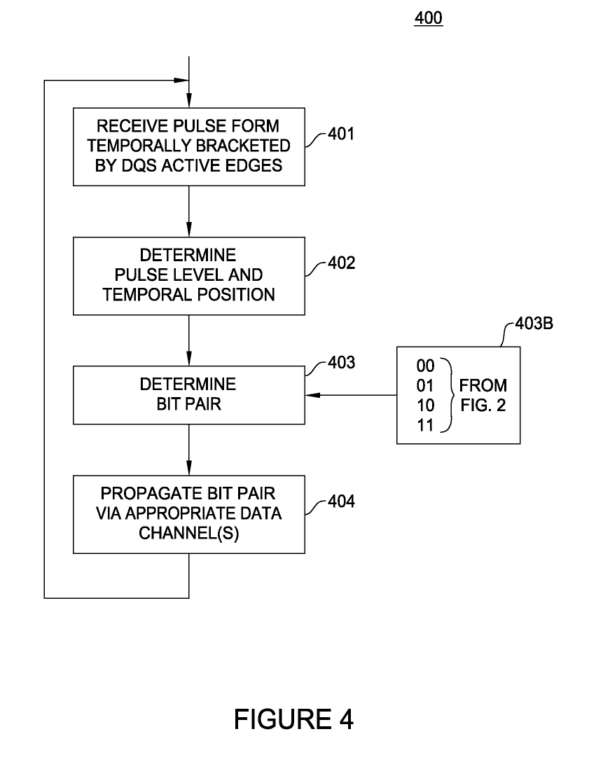

According to an embodiment of the invention, the I/O circuit 106 receives bit pairs (or other sized bit groups) from the memory array 120. The bit pairs or groups are then encoded in CODEC 155_{B} and propagated from the memory device to other devices such as the controller 150 depicted in FIG. 1A. The bit pairs/groups are encoded to produce pulse forms such as described below with respect to FIG. 2.

FIG. 2 is a graphical representation depicting data encoding according to one embodiment of the invention. Specifically, FIG. 2 displays a set of data representative pulse forms (waveform combinations) realizable with two available pulse levels and two available temporal positions per data access cycle. FIG. 2 depicts pulse forms of encoded data bit pairs for each of four possible data bit pairs; namely, “00,” “01,” “10,” and “11,” as expressed by, respectively, waveforms 230, 240, 210, and 220. Each waveform depicts signal level as a function of time. Each waveform is initiated by a first clock pulse (DQS) active edge 201 and terminated by a second clock pulse active edge 202. These active edges may be provided by a single clock pulse (e.g., DDR DRAM) or two different clock pulses (e.g., SDR DRAM).

As depicted in FIG. 2, where two bits are encoded according to the invention, the pulse level of an encoded data word determines the first bit of the word, and the temporal position of the pulse (e.g., early or late) within an access cycle determines the second bit of the word.

In the first waveform 210, a high pulse level transmitted “early” (e.g., in the first portion of a DQS cycle) represents the transfer of a binary ‘10.’ In the second waveform 220, a high pulse level transmitted “late” (e.g., in the second portion of a DQS cycle) represents the transfer of a binary ‘11.’ In the third waveform 230, a low pulse level transmitted “early” (e.g., in the first portion of a DQS cycle) represents the transfer of a binary ‘00.’ In the fourth waveform 240, a low pulse level transmitted “late” (e.g., in the second portion of a DQS cycle) represents the transfer of a binary ‘01.’ It will be appreciated that the particular waveforms depicted as representing particular bit pairs may instead be used to represent different bit pairs.

FIG. 3 is a flow diagram of method 300 for encoding data bit pairs according to an embodiment of the invention. At step 301, a first (or next) bit pair to be encoded is received at, illustratively, the data I/O circuit 106 after transmission from the data array 120. At step 302, the appropriate pulse form for encoding the bit pair is determined. Referring to box 302B, the appropriate pulse form for the bit pair is selected from, illustratively, the pulse forms discussed above with respect to FIG. 2; namely, specific pulse levels and temporal positions associated with the 00, 01, 10 and 11 bit pairs. At step 303, the pulse form determined at step 302 is provided via the appropriate data channel (i.e., DQ). Referring to box 303B, the provided pulse form will be temporally bracketed within DQS active edges, thereby defining one data access cycle including the encoded bit pair.

FIG. 4 depicts a flow diagram of a method 400 for decoding data bit pair pulse forms according to an embodiment of the invention. At step 401, a pulse form temporally bracketed by DQS active edges is received. At step 402, the pulse level and temporal position associated with the pulse form is determined. At step 403, the bit pair represented by the pulse form is determined. Referring to box 403B, the bit pair is illustratively determined according to the pulse form encoding discussed above with respect to FIG. 2; namely, specific bit pairs (00, 01, 10, 11) being associated with particular pulse levels located at particular temporal positions within a time interval defined by the DQS active edges. At step 404, the determined bit pair is propagated via appropriate data channel(s) to, illustratively, the memory array 120. That is, the received/decoded bit pair is propagated via two parallel data channels or one serial data channels to the memory array 120.

In various embodiments of the current invention represented by memory device 100 of FIG. 1B, the temporally arranged pulses 210, 220, 230, and 240 of FIG. 2 are propagated using individual paths within DQ[N:0] of Data I/O 106. Although Data I/O 106 is depicted as residing in a memory system in these embodiments, the described methods of encoding, decoding, and data transfer should not be construed as being useful only within a memory device. Rather, the described methods can be used in any type of data transfer device where reducing the number of data bearing signal pins and/or current used to access data is desired.

It will be evident to those skilled in the art and informed by the present disclosure that the invention may be expanded to encoding/decoding methods applicable to more than data bit pairs. Specifically, the invention comprises a methodology adapted to use a pulse level/position characteristic of a pulse waveform to define thereby a multiple bit data word. The word may have two or more bits. In the case of an M-bit data word, each possible bit combination may be conveyed using M levels and M temporal positions within a time interval defined by the active edges of the data strobe. In a pure digital system, such extensions may not be appropriate. However, in systems where multiple levels are available, such extensions may be used to allow for the transfer of multiple bits of data per access cycle. For every additional bit that can be transferred during one access cycle, the number of DQ pins used to maintain the same data transfer rate may be reduced.

Hence, while the foregoing is directed to embodiments of the present invention, other and further embodiments of the invention may be devised without departing from the basic scope thereof, which is determined by the claims that follow.

What is claimed is:

1. A method for encoding data, comprising:
associating a first data bit of a pair of data bits with a bit-indicative pulse level;
associating a second data bit of the pair of data bits with a bit-indicative temporal position within a time interval defined by data strobe active edges; and
providing a pulse exhibiting the associated pulse level within the associated time interval.

2. The method of claim 1, wherein:
the bit-indicative pulse level comprises a high level representing a logical “1” and a low level representing a logical “0.”

3. The method of claim 1, wherein:
the bit-indicative temporal position comprises an early position representing a logical “1” and a late position representing a logical “0.”

4. The method of claim 1, wherein:
the bit-indicative pulse level comprises a high level representing a logical “0” and a low level representing a logical “1.”

5. The method of claim 1, wherein:
the bit-indicative temporal position comprises an early position representing a logical “0” and a late position representing a logical “1.”

6. The method of claim 1, wherein:
the pair of data bits are received from a memory array; and
the pulse is provided to a data path.

7. A method for decoding data, comprising:
receiving a pulse from a data path within a time interval defined by data strobe active edges;
associating a first data bit of a pair of data bits with a level of the pulse; and
associating a second data bit of the pair of data bits with a temporal position within the time interval defined by data strobe active edges.

8. The method of claim 7, further comprising:
associating a first data bit of the pair of data bits with a temporal position within the time interval defined by data strobe active edges; and
associating a first data bit of a pair of data bits with a level of the pulse.

9. An apparatus, comprising:
circuitry configured to:
receive a sequence of pulse forms, each pulse form representing a respective plurality of data bits according to a respective level and temporal position of a pulse within a time interval defined by data strobe active edges; and
determine, for each pulse form, the data bits conveyed thereby.

10. The apparatus of claim 9, further comprising:
circuitry configured to:
transmit a sequence of pulse forms, each pulse form representing a respective plurality of data bits according to a respective level and temporal position of a pulse within a time interval defined by data strobe active edges.

11. A memory device, comprising:
circuitry configured to:
receive a sequence of pulse forms, each pulse form representing a respective plurality of data bits according to a respective level and temporal position of a pulse within a time interval defined by data strobe active edges;
determine, for each pulse form, the data bits conveyed thereby; and
store the data bits in an accessible repository.

12. The memory device of claim 11, further comprising:
circuitry configured to:
retrieve the data bits from the accessible repository; and
transmit a sequence of pulse forms, each pulse form representing a respective plurality of data bits according to a respective level and temporal position of a pulse within a time interval defined by data strobe active edges.

13. The memory device of claim 12 further comprising one or more signal paths on which the sequence of pulse forms representing a respective plurality of data bits can be propagated.

14. The memory device of claim 12, wherein the accessible repository comprises a plurality of addresses into which the data bits can be stored.

15. The memory device of claim 14, further comprising:
one or more signal paths, whereon signals are received indicating into which of the plurality of addresses the data bits are to be stored; and
one or more signal paths, whereon signals are transmitted indicating from which of the plurality of addresses the data bits are to be retrieved.

16. The memory device of claim 14, further comprising:
.one or more signal paths, whereon signals are received indicating from which of the plurality of addresses the data bits are to be retrieved; and
one or more signal paths, whereon signals are transmitted indicating into which of the plurality of addresses the data bits are to be stored.

17. The memory device of claim 14, further comprising:
one or more signal paths to transmit the data strobe active edges; and
one or more signal path to receive the data strobe active edges.

18. The memory device of claim 14, wherein the memory device is a DDR-DRAM device.

19. The memory device of claim 18, wherein the data strobe active edges comprise the rising and falling edges of the data strobe signal.

20. A controller, comprising:
circuitry configured to:
issue a command to a memory device, whereby the memory device receives a sequence of data symbols, each data symbol representing a respective plurality of data bits according to a respective pulse level and temporal position of the pulse within a time interval defined by data strobe active edges, and stores said plurality of data bits; and
receive a command from a memory device, whereby the memory device retrieves a respective plurality of data bits, and transmits a sequence of waveforms, each waveform representing the respective plurality of data bits according to a respective pulse level and temporal position within a time interval defined by data strobe active edges.

21. The controller of claim 20 further comprising:
circuitry configured to:
receive the data strobe active edges from the memory device; and
transmit the data strobe active edges to the memory device.

22. The controller of claim 20, wherein the memory device comprises a plurality of addresses into which the respective plurality of data bits can be stored.

23. The controller of claim 22, further comprising:
one or more signal paths, whereon the controller indicates to the memory device into which of the plurality of addresses the plurality of data bits is to be stored; and
one or more signal paths, whereon the controller indicates to the memory device from which of the plurality of addresses the plurality of data bits is to be retrieved.

24. The controller of claim 22, further comprising:
one or more signal paths, whereon the memory device indicates to the controller into which of the plurality of addresses the plurality of data bits is to be stored; and
one or more signal paths, whereon the memory device indicates to the controller from which of the plurality of addresses the plurality of data bits is to be retrieved.
